(19) United States
(12) Patent Application Publication
(10) Pub. No.: US 2009/0230482 A1
(43) Pub. Date: Sep. 17, 2009

(54) SEMICONDUCTOR DEVICE AND MANUFACTURING METHOD THEREOF

(75) Inventors: Yoshiaki KATO, Toyama (JP); Yoshiharu ANDA, Osaka (JP); Akiyoshi TAMURA, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/404,562

(22) Filed: Mar. 16, 2009

(30) Foreign Application Priority Data
Mar. 17, 2008 (JP) 2008-068339

(51) Int. Cl. H01L 27/088; H01L 21/28

(52) U.S. Cl. 257/392; 438/591; 257/E27.061; 257/E21.19

(57) ABSTRACT

A semiconductor device in which an E-FET and a D-FET are integrated on the same substrate, wherein an epitaxial layer includes, in the following order from the semiconductor substrate: a first threshold adjustment layer that adjusts a threshold voltage of a gate of the E-FET and a threshold voltage of a gate of the D-FET; a first etching-stopper layer that stops etching performed from an uppermost layer to a layer abutting on the first etching-stopper layer; a second threshold adjustment layer that adjusts the threshold voltage of the gate of the D-FET; and a second etching-stopper layer that stops the etching performed from the uppermost layer to a layer abutting on the second etching-stopper layer, and at least one of the first etching-stopper layer and the second threshold adjustment layer includes an n-type doped region.

### BACKGROUND OF THE INVENTION

(1) Field of the Invention

The present invention relates to a semiconductor device and a manufacturing method thereof, and especially to a semiconductor device in which two or more types of field-effect transistors each having a different threshold voltage are integrated on a compound semiconductor substrate.

(2) Description of the Related Art

A field-effect transistor formed on a semi-insulating substrate made of GaAs (hereinafter referred to as GaAsFET) has been used for a power amplifier or switch of a communication device, especially a mobile phone terminal, due to its high performance. A monolithic microwave integrated circuit (hereinafter referred to as GaAsMMIC) on which active elements such as the GaAsFET and passive elements such as resistance elements and capacitance elements are integrated have been widely in practical use.

As higher functionality and higher performance of the GaAsMMIC have been required in recent years, a GaAsMMIC has been demanded that includes a logic circuit including an enhancement-mode FET (hereinafter referred to as E-FET) and the aforesaid power amplifier or switch including a depletion-mode FET (hereinafter referred to as D-FET), that is, an E/D-FET in which the E-FET and the D-FET are both mounted on the same substrate.

Examples of conventional E/D-FETs include the semiconductor device disclosed in Japanese Unexamined Patent Application Publication No. 2007-27333 (Patent Reference 1). The semiconductor device disclosed in Patent Reference 1 is a switch integrated circuit device that includes, on a semiconductor substrate, a switch circuit, which is caused by a depletion-mode high electron mobility transistor (HEMT) to switch high-frequency analog signals, and a logic circuit including an enhancement-mode HEMT that is integrated on the same substrate as the depletion-mode HEMT. The following will describe the structure and functions of the conventional semiconductor device disclosed in Patent Reference 1.

FIG. 3 shows a structural sectional view of the conventional semiconductor device disclosed in Patent Reference 1. A conventional semiconductor device 500 in the figure includes a semiconductor layer 600, source electrodes 630 and 631, a drain electrode 640, gate electrodes 650 and 651, and a insulating film 700.

The semiconductor layer 600 includes a GaAs substrate 601, a buffer layer 602, a first donor layer 603, a spacer layer 604, an electron transit layer 605, a second donor layer 606, a first undoped layer 607, a second undoped layer 608, a third undoped layer 609, a fourth undoped layer 610, and a cap layer 611. The semiconductor layer 600 is laminated in this order of the layers. The first undoped layer 607 is made of undoped AlGaAs that is lattice matched with the second donor layer 606. The second undoped layer 608 is made of undoped InGaP that is lattice matched with the first undoped layer 607. The third undoped layer 609 is made of undoped AlGaAs that is lattice matched with the second undoped layer 608. The fourth undoped layer 610 is made of undoped InGaP that is lattice matched with the third undoped layer 609. The cap layer 611 is lattice matched with the fourth undoped layer 610.

The source electrodes 630 and 631 and the drain electrode 640 are formed on the surface of the cap layer 611.

The gate electrode 650 is arranged between the source electrode 630 and the drain electrode 640, formed on the surface of the first undoped layer 607, and made of Pt that is partially embedded in the first undoped layer 607. The gate electrode 650 functions as the gate of the enhancement-mode FET.

The gate electrode 651 is arranged between the source electrode 631 and the drain electrode 640, formed on the surface of the second undoped layer 608, and made of Pt that is partially embedded in the second undoped layer 608. The gate electrode 651 functions as the gate of the depletion-mode FET.

The insulating film 700 includes nitride films 701, 702, and 703, and coats the first undoped layer 607 and the second undoped layer 608 that are exposed around the gate electrodes 650 and 651.

The electron transit layer 605 forms a current path with electrons generated from donor impurities of the first donor layer 603 and the second donor layer 606 that are adjacent to the electron transit layer 605.

The gate electrode 650 is formed on the surface of the first undoped layer 607, and the film thickness of the first undoped layer 607 is designed to maintain a threshold voltage at the gate of the E-FET.

The gate electrode 651 is formed on the surface of the second undoped layer 608. A higher gate voltage can be applied to the second undoped layer 608 made of InGaP, since InGaP has a larger band gap than AlGaAs does. Furthermore, the second undoped layer 608 functions as an etching-stopper layer for the third undoped layer 609 that abuts thereon.

Each of the undoped layers of the D-FET and the E-FET has a different film thickness, because the D-FET and the E-FET each have a different threshold voltage at a gate that controls a drain current.

The total film thickness of the first undoped layer 607 and the second undoped layer 608 is designed to maintain a threshold voltage at the gate of the D-FET.

The fourth undoped layer 610 functions as an etching-stopper layer for the cap layer 611. Moreover, InGaP, the material of the fourth undoped layer 610, functions to protect operation regions from plasma damages when plasma etching the cap layer 611, because InGaP is resistant to external chemical stress due to its resistance to oxidization.

Since the second donor layer 606, the first undoped layer 607, the second undoped layer 608, the third undoped layer 609, the fourth undoped layer 610, and the cap layer 611 are lattice matched with each other, less crystal distortion occurs, and reproducibility of the electrical characteristics of FETs is assured.

As described above, the conventional semiconductor device shown in FIG. 3 is structured in such a manner that the undoped InGaP layers and the undoped AlGaAs layers are repeatedly laminated, so that the D-FET and the E-FET each having the different threshold voltage at the gate are reproducibly formed on the same substrate.

### SUMMARY OF THE INVENTION

However, InGaP, the material of the second undoped layer 608 and the fourth undoped layer 610, spontaneously polarizes. As with the above-mentioned conventional structure, in an epitaxial structure laminated in order of undoped AlGaAs/InGaP/AlGaAs, the spontaneous polarization causes uneven distribution and polarization of positive charges to the upper interface of InGaP and negative charges to the lower interface of InGaP. As a result, the positive charges in the upper interface of InGaP block electrons in their passage of each undoped layer in a longitudinal direction, the electrons flowing from a source to a drain when an FET is in on-state. This increases resistance components under an ohmic electrode in the longitudinal direction. The resistance components become parasitic resistance when the FET is in on-state, and increase on-resistance that is an important characteristic of the FET.

The increase in the on-resistance causes a loss of the high frequency characteristic of the FET, so that the essential characteristics of the FET cannot be extracted. In particular, power loss, which is a performance parameter of a high-frequency switch, increases.

As described above, in the conventional semiconductor device in which the E-FET and the D-FET are integrated by laminating the undoped layers that are lattice matched with each other, the spontaneous polarization of the semiconductor materials that are heterojunctioned prevents reduction in source-to-drain on-resistance that is especially important FET performance.

In the view of the above-mentioned problem, the objective of the present invention is to reduce the source-to-drain on-resistance in the semiconductor device in which the E-FET and the D-FET are integrated on the same substrate.

In order to achieve the above objective, a semiconductor device according to the present invention is a semiconductor device in which an enhancement-mode field-effect transistor and a depletion-mode field-effect transistor are adjacently integrated in a planar direction of a semiconductor substrate using a semiconductor layer laminated on the semiconductor substrate, wherein the semiconductor layer includes: a first threshold adjustment layer that is formed on the semiconductor substrate and adjusts a threshold voltage of a gate of the enhancement-mode field-effect transistor and a threshold voltage of a gate of the depletion-mode field-effect transistor; a first etching-stopper layer that is formed on the first threshold adjustment layer and stops etching performed from an uppermost layer; a second etching-stopper layer that is formed on the second threshold adjustment layer and stops the etching performed from the uppermost layer, and at least one of the first etching-stopper layer and the second threshold adjustment layer includes an n-type doped region.

Accordingly, since at least one of the first etching-stopper layer and the second threshold adjustment layer includes the n-type doped region, the accumulation of positive charges in an upper hetero-interface of the first etching-stopper layer is suppressed and a barrier to electron conduction is lowered. Thus, it becomes possible to reduce longitudinal parasitic resistance components in a drain current path of an FET.

Furthermore, the second etching-stopper layer may include the n-type doped region.

Accordingly, since the second etching-stopper layer includes the n-type doped region, the accumulation of positive charges in an upper interface of the second etching-stopper layer is suppressed and a barrier to electron conduction is lowered. Thus, it becomes possible to reduce longitudinal parasitic resistance components in a drain current path of an FET.

Moreover, the first threshold adjustment layer and the second threshold adjustment layer are preferably made of AlGaAs.

Accordingly, since the AlGaAs having a wide band gap is used for the first threshold adjustment layer and the second threshold adjustment layer, gate electrodes can have high pressure resistance of Schottky in the forward direction.

In addition, the first etching-stopper layer and the second etching-stopper layer are preferably made of InGaP.

Accordingly, since the InGaP is used for the first etching-stopper layer and the second etching-stopper layer, the first and second etching-stopper layers can be lattice matched with adjacent AlGaAs and have high etching selectivity with respect to the AlGaAs and so on. Thus, it becomes possible to prevent deterioration of reproducibility due to crystal distortion, asperities of a laminate interface, and impurities in the laminate layer.

Furthermore, the InGaP may have a disordered structure.

Accordingly, using, as the InGaP, the disordered structure in which an atomic arrangement is random and which suppresses spontaneous polarization can reduce on-resistance.

Moreover, the second threshold adjustment layer includes the n-type doped region, and the n-type doped region is preferably included within a distance of 7 nm inclusive from a contact interface between the second threshold adjustment layer and the first etching-stopper layer.

Accordingly, since the n-type doping is efficiently performed near an interface where positive charges are accumulated, the on-resistance can be reduced.

In addition, the second threshold adjustment layer includes the n-type doped region, and preferably the n-type doped region is uniformly doped n-type of a film thickness of between 1 nm and 6 nm inclusive, in the planar direction of the semiconductor substrate.

Accordingly, as the positive charges accumulated in the upper hetero-interface of the first etching-stopper layer are uniformly reduced across the whole interface in a film surface direction, a barrier to electron conduction is uniformly lowered across the whole interface. Thus, low on-resistance having high reproducibility can be achieved. Furthermore, as the n-type doped region is locally formed in a film-laminating direction, the on-resistance can be reduced with high doping efficiency.

Moreover, the second threshold adjustment layer includes the n-type doped region, and the n-type doping may be delta doping.

Accordingly, since the n-type doping is localized to every atomic layer, charges are efficiently adjusted at a distance near an interface, and an increase in the on-resistance can be suppressed.

In addition, the second threshold adjustment layer includes the n-type doped region, and a surface concentration of the n-type doping is preferably between 3×10¹¹/cm² and 5×10¹²/cm² inclusive.

Accordingly, since adequate n-type doping is performed at a distance near an interface where charges are accumulated, on-resistance can be reduced as well as it becomes possible to prevent electrons from flowing to layers other than a channel layer having high electron mobility.

Furthermore, the first etching-stopper layer may be uniformly doped n-type.

Accordingly, the accumulation of the positive charges in the upper hetero-interface of the first etching-stopper layer is suppressed, and the barrier to the electron conduction is lowered. Thus, it becomes possible to reduce longitudinal on-resistance of a drain current of an FET.

In addition, a surface concentration of the n-type doping is preferably between 3×10¹¹/cm² and 5×10¹²/cm² inclusive.

Accordingly, since the adequate n-type doping is performed at the distance near the interface where the charges are accumulated, the on-resistance can be reduced as well as it becomes possible to prevent the electrons from flowing to the layers other than the channel layer having high electron mobility.

Moreover, the first etching-stopper layer includes the n-type doped region, and the n-type doping may be delta doping.

Accordingly, since the n-type doping is localized to every atomic layer, the charges are efficiently adjusted at the distance near the interface, and the increase in the on-resistance can be suppressed.

It is to be noted that the present invention can be realized not only as the semiconductor device including the above characteristic units but also as a manufacturing method thereof in which the characteristic units included in the semiconductor device are steps.

With the present invention, in the semiconductor device in which the E-FET and the D-FET are integrated on the same substrate, since the accumulation of the positive charges in the laminate interface forming the drain current path is suppressed and the barrier to the electron conduction is lowered, the on-resistance of the FET can be reduced.

### FURTHER INFORMATION ABOUT TECHNICAL BACKGROUND TO THIS APPLICATION

The disclosure of Japanese Patent Application No. 2008-068339 filed on Mar. 17, 2008 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the accompanying drawings:

FIG. 1 is a structural sectional view of a semiconductor device according to Embodiment 1 of the present invention;

FIG. 2 is a structural sectional view of a semiconductor device according to Embodiment 2 of the present invention; and

FIG. 3 shows a structural sectional view of a conventional semiconductor device disclosed in Patent Reference 1.

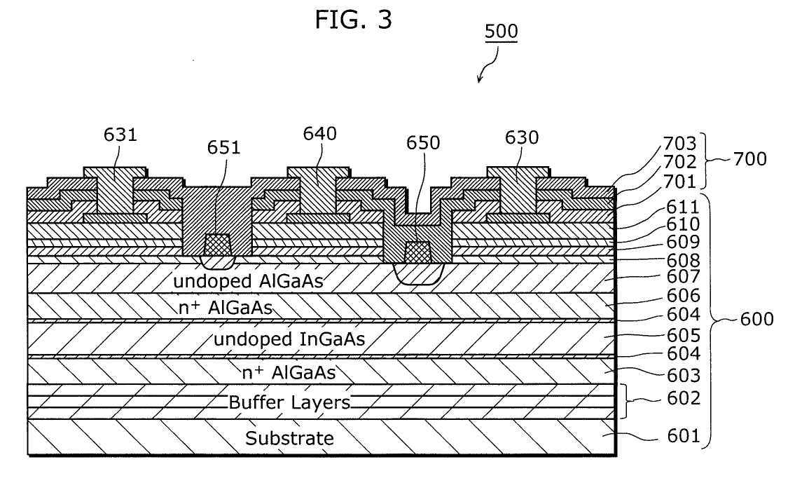

### DESCRIPTION OF THE PREFERRED EMBODIMENT(S)

### Embodiment 1

A semiconductor device according to Embodiment 1 is a semiconductor device that includes an enhancement-mode field-effect transistor (hereinafter referred to as E-FET) and a depletion-mode field-effect transistor (hereinafter referred to as D-FET) on a semiconductor substrate, and includes: a first etching-stopper layer that is formed on a first threshold adjustment layer and adjusts threshold voltages of gates of the E-FET and the D-FET; and a second threshold adjustment layer that is formed on the first threshold adjustment layer and adjusts the threshold voltage of the gate of the D-FET, wherein the second threshold adjustment layer includes an n-type doped region. With this, since the occurrence of charges resulting from a multi-layer heterostructure is controlled and an electron barrier is lowered, on-resistance against a drain current passing a laminate interface is reduced.

The following will describe in detail the semiconductor device according to the present embodiment of the present invention with reference to the drawings.

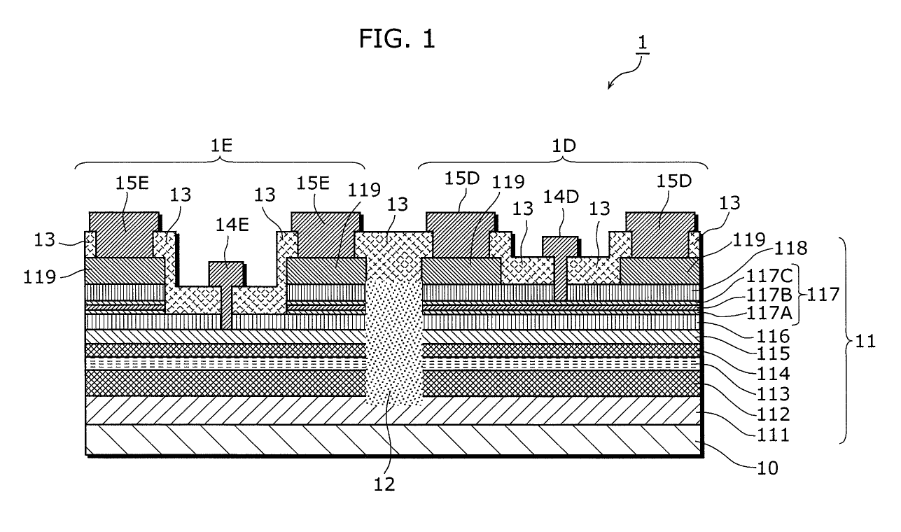

FIG. 1 is a structural sectional view of the semiconductor device according to Embodiment 1 of the present invention. A semiconductor device 1 shown in the figure includes an E-FET region 1E where an E-FET is formed and a D-FET region 1D where a D-FET is formed. In addition, the semiconductor device 1 includes a semiconductor substrate 10, an epitaxial layer 11, an isolation region 12, an insulating film 13, gate electrodes 14D and 14E, and ohmic electrodes 15D and 15E.

The semiconductor substrate 10 is made of semi-insulating GaAs.

The epitaxial layer 11 is formed through crystal growth of a semiconductor layer on the semiconductor substrate 10. From bottom up of the semiconductor substrate 10, the epitaxial layer 11 includes buffer layers 111 and 112, a channel layer 113, a donor layer 114, a first threshold adjustment layer 115, a first etching-stopper layer 116, a second threshold adjustment layer 117, a second etching-stopper layer 118, and a contact layer 119.

The buffer layer 111 is, for instance, made of undoped GaAs and has a film thickness of 1 μm.

The buffer layer 112 is, for instance, made of undoped AlGaAs. The buffer layers 111 and 112 function to reduce lattice mismatching between the epitaxial layer 11 and the semiconductor substrate 10.

The channel layer 113 is a layer where carriers travel. The channel layer 113 is, for instance, made of undoped In_{0.2}Ga_{0.8}As and has a film thickness of 10 nm.

The donor layer 114 is a layer where electrons that are the carriers are donated to the channel layer 113, and is, for instance, made of AlGaAs to which Si that is an n-type impurity ion is doped. The film thickness of the donor layer 114 is 10 nm.

The first threshold adjustment layer 115 is a layer where a threshold voltage of the gate of the E-FET and a threshold voltage of the gate of the D-FET are adjusted. The first threshold adjustment layer 115 is, for instance, made of undoped AlGaAs and has a film thickness of 5 nm.

The first etching-stopper layer 116 functions as an etching-stopper layer that stops etching performed on from the uppermost layer to the second threshold adjustment layer 117 that abuts on the first etching-stopper layer 116. The first etching-stopper layer 116 is, for instance, made of InGaP having a disordered structure and has a film thickness of 8 nm. Here, the disordered structure is a structure where an atomic arrangement is not in order but in disorder. As this suppresses spontaneous polarization of InGaP, uneven distribution of positive charges around a hetero-interface is suppressed. Thus, a barrier to conduction of electrons that are the carriers of the drain current is lowered, and the on-resistance is reduced. InGaP having the disordered structure can be, for example, formed by controlling film-forming conditions such as a film-forming temperature.

It is to be noted that n-type doping may be uniformly performed on the first etching-stopper layer 116. Preferably, the surface concentration of the n-type doping is between 3×10¹¹/cm² and 5×10¹²/cm² inclusive.

The second threshold adjustment layer 117 is a layer that adjusts the threshold voltage of the gate of the D-FET, and includes adjustment layers 117A, 117B, and 117C. The adjustment layers 117A, 117B, and 117C are, for example, made of AlGaAs. It is desirable to use materials with high etching selectivity between adjacent layers. The adjustment layer 117B has, for example, the surface concentration of 5×10¹²/cm², is doped with n-type doping of Si, and has a film thickness of 3 nm.

It is to be noted that the surface concentration of the n-type doping to the second threshold adjustment layer 117 is preferably between 3×10¹¹/cm² and 5×10¹²/cm² inclusive. When the surface concentration of the n-type doping is smaller than 3×10¹¹/cm², spontaneous polarization of a layer that is made of InGaP and adjacent to the second adjustment layer 117 is not sufficiently suppressed, and the effect of reducing the on-resistance cannot be fully obtained. On the other hand, when the surface concentration of the n-type doping is greater than 5×10¹²/cm², electrons flow to layers other than the channel layer 113 having high electron mobility, and so-called parallel conductance occurs. In this case, though the on-resistance is reduced, the controllability of the drain current by the gate voltage is lowered.

It is to be noted that the n-type doping may be delta doping. Here, the delta doping denotes the introduction of an impurity atomic layer that is localized to a single atomic layer in a semiconductor crystal. The delta doping, for example, provides impurity atoms to a surface on which crystal growth is temporarily suspended, using a thin-film forming technique having film-thickness controllability at the atomic level such as molecular beam epitaxy (MBE) and metalorganic chemical vapor deposition (MOCVD). The delta doping is also referred to as sheet doping. Since performing the delta doping on the second threshold adjustment layer 117 causes the n-type doping to be localized to each of single atomic layers, charges are efficiently adjusted at a distance near the interface of the first etching-stopper layer 116, and the increase in the on-resistance can be suppressed.

Furthermore, the n-type doping needs to be in the second threshold adjustment layer 117, and the adjustment layers 117A and 117C may not be necessary. n-type delta doping to the second threshold adjustment layer 117 can be realized by, for example, temporarily suspending epitaxial growth and filing gas including Si.

In addition, in the second threshold adjustment layer 117, an n-type doped region is preferably formed within a distance of 7 nm inclusive from an interface with the first etching-stopper layer 116. Accordingly, as the n-type doping is performed near the interface where positive charges are accumulated, the on-resistance can be efficiently reduced.

Moreover, in the second threshold adjustment layer 117, preferably, the n-type doped region is uniformly doped with a film thickness between 1 nm and 6 nm inclusive. Accordingly, as positive charges accumulated in the upper hetero-interface of the first etching-stopper layer 116 are uniformly reduced across the whole interface in a film surface direction, a barrier to the electron conduction is uniformly lowered across the whole interface. Thus, low on-resistance having high reproducibility can be achieved. Furthermore, as the n-type doped region is locally formed in a film-laminating direction, the on-resistance can be reduced with high doping efficiency.

Example of methods for forming uniform n-type doped region include, for instance, mixing gas including Si in epitaxial film forming of the second threshold adjustment layer 117.

The second etching-stopper layer 118 functions as an etching-stopper layer that stops etching performed on from the uppermost layer to the contact layer 119 that abuts on the second etching-stopper layer 118. The second etching-stopper layer 118 is, for instance, made of InGaP having a disordered structure and has a film thickness of 8 nm. In comparison with AlGaAs, InGaP has a quite low etching rate for wet-etching using phosphate. Thus, the first etching-stopper layer 116 and the second etching-stopper layer 118 function as an etching-stopper layer having high etching selectivity.

It is to be noted that the surface concentration of the n-type doping to the second etching-stopper layer 118 is also preferably between 3×10¹¹/cm² and 5×10¹²/cm² inclusive. This can further reduce the on-resistance in a drain current path.

The contact layer 119 is divided into four regions, and either the ohmic electrodes 15D or the ohmic electrodes 15E are connected to each of the four regions. The contact layer 119 is two-layered. The lower layer is made of n-type GaAs and has a film thickness of 50 nm, and the upper layer is made of n-type InGaAs and has a film thickness of 50 nm.

The isolation region 12 is formed through ion implantation, and electrically isolates the E-FET region 1E and the D-FET region 1D.

The insulating film 13 is formed on the epitaxial layer 11 and the isolation region 12 and, for example, made of SiN.

The gate electrode 14E is formed to be implanted in an opening formed in the insulating film 13 of the E-FET region 1E and the first etching-stopper layer 116. The gate electrode 14E is, for example, made of Ti/Al/Ti, and forms a Schottky barrier junction with the first threshold adjustment layer 115.

The gate electrode 14D is formed to be implanted in an opening formed in the insulating film 13 of the D-FET region 1D and the second etching-stopper layer 118. The gate electrode 14D is, for example, made of Ti/Al/Ti, and forms a Schottky barrier junction with the second threshold adjustment layer 117.

The ohmic electrodes 15E are a source electrode and a drain electrode of the E-FET, respectively, and separately formed to sandwich the gate electrode 14E. The ohmic electrodes 15E each are electrically connected to the channel layer 113 via the contact layer 119 of the E-FET region 1 E, the second etching-stopper layer 118, the second threshold adjustment layer 117, the first etching-stopper layer 116, the first threshold value adjustment layer 115, and the donor layer 114. In addition, the ohmic electrodes 15E are formed to be implanted in openings formed by the insulating film 13 of the E-FET region 1E, and form ohmic contact with the contact layer 119. The drain current path of the E-FET is formed through the connection of the ohmic electrodes 15E.

The ohmic electrodes 15D are a source electrode and a drain electrode of the D-FET, respectively, and separately formed to sandwich the gate electrode 14D. The ohmic electrodes 15D are connected to the channel layer 113 via a laminated epitaxial structure that is the same as the E-FET. Furthermore, the ohmic electrodes 15D are formed to be implanted in openings formed by the insulating film 13 of the D-FET region 1D, and form ohmic contact with the contact layer 119. The drain current path of the D-FET is formed through the connection of the ohmic electrodes 15D.

Here, a manufacturing process of the semiconductor device according to Embodiment 1 of the present invention will be described.

Each of the layers included in the epitaxial layer 11 is consistently film-formed through, for example, the MOCVD or the MBE.

First, the buffer layers 111 and 112 made of undoped GaAs, the channel layer 113 made of undoped In_{0.2}Ga_{0.8}As and having a film thickness of 10 nm, and the donor layer 114 made of AlGaAs and having a film thickness of 10 nm to which Si is doped are laminated on the semiconductor substrate 10 in this order.

Next, the first threshold adjustment layer 115 made of undoped AlGaAs and having a film thickness of 5 nm is laminated on the donor layer 114.

Next, the first etching-stopper layer 116 made of InGaP and having a film thickness of 8 nm is laminated on the first threshold adjustment layer 115. Here, the first etching-stopper layer 116 preferably has a disordered structure. In addition, preferably, the n-type doping is uniformly performed on the first etching-stopper layer 116.

Next, the adjustment layer 117A made of AlGaAs and the adjustment layer 117B having a film thickness of 3 nm are laminated on the first etching-stopper layer 116, and the adjustment layer 117B is doped with the n-type doping of Si. Subsequently, the adjustment layer 117C made of AlGaAs is laminated on the n-type doped adjustment layer 117B. The n-type doping performed on the adjustment layer 117B may be the delta doping.

Next, the second etching-stopper layer 118 that is made of InGaP having a disordered structure and has a film thickness of 8 nm is laminated on the adjustment layer 117C. Here, preferably, the n-type doping is performed on the second etching-stopper layer 118.

Next, the contact layer 119 that includes a lower layer made of n-type GaAs and having a film thickness of 50 nm and an upper layer made of n-type InGaAs and having a film thickness of 50 nm is laminated on the second etching-stopper layer 118.

Next, with respect to the epitaxial layer 11 laminated in the above manner, the isolation region 12, the insulating film 13, the gate electrodes 14D and 14E, and the ohmic electrode 15D and 15E are formed by laminating electrodes and an insulating film and through proper doping processing and etching processing.

As described above, in the semiconductor device 1 in the present embodiment, since the occurrence of charges resulting from the multi-layer heterostructure is controlled and the electron barrier is lowered by including the n-type doped second threshold adjustment layer 117 in the semiconductor device 1, the on-resistance against the drain current passing the laminate interface is reduced.

### Embodiment 2

A semiconductor device according to Embodiment 2 is a semiconductor device that includes an E-FET and a D-FET on a semiconductor substrate, and includes: a first etching-stopper layer that is formed on a first threshold adjustment layer and adjusts threshold voltages of gates of the E-FET and the D-FET; and a second threshold adjustment layer that is formed on the first threshold adjustment layer and adjusts the threshold voltage of the gate of the D-FET, wherein the first etching-stopper layer includes an n-type doped region. With this, since the occurrence of charges resulting from a multi-layer heterostructure is controlled and an electron barrier is lowered, on-resistance against a drain current passing a laminate interface is reduced.

The following will describe in detail the semiconductor device according to Embodiment 2 of the present invention with reference to the drawings.

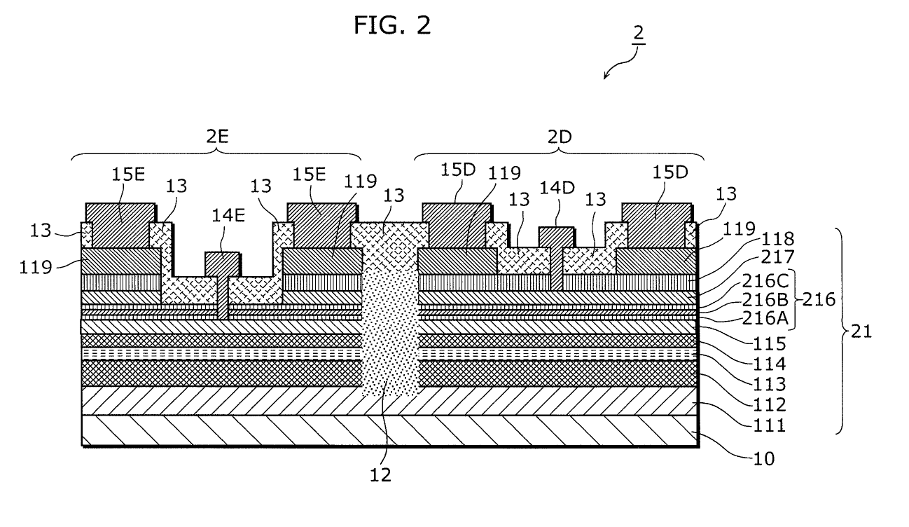

FIG. 2 is a structural sectional view of the semiconductor device according to Embodiment 2 of the present invention. A semiconductor device 2 shown in the figure includes an E-FET region 2E where an E-FET is formed and a D-FET region 2D where a D-FET is formed. In addition, the semiconductor device 2 includes a semiconductor substrate 10, an epitaxial layer 21, an isolation region 12, an insulating film 13, gate electrodes 14D and 14E, and ohmic electrodes 15D and 15E.

The epitaxial layer 21 is formed through crystal growth of a semiconductor layer on the semiconductor substrate 10. From bottom up of the semiconductor substrate 10, the epitaxial layer 21 includes buffer layers 111 and 112, a channel layer 113, a donor layer 114, a first threshold adjustment layer 115, a first etching-stopper layer 216, a second threshold adjustment layer 217, a second etching-stopper layer 118, and a contact layer 119.

In comparison with the semiconductor device 1 according to Embodiment 1 shown in FIG. 1, the semiconductor device 2 according to Embodiment 2 shown in FIG. 2 differs only in the structure and function of the epitaxial layer 21. The description of the same points as in the semiconductor device 1 shown in FIG. 1 is omitted, and the following will describe only differences.

A first etching-stopper layer 216 includes stopper layers 216A, 216B, and 216C. Each of the stopper layers 216A, 216B, and 216C is, for instance, made of InGaP having a disordered structure and has a film thickness of 8 nm. This structure may be a factor for reducing on-resistance against a drain current. The stopper layer 216B has, for example, the surface concentration of 5×10¹²/cm² and a film thickness of 3 nm, and is doped with the n-type doping of Si.

It is to be noted that the surface concentration of the n-type doping to the first etching-stopper layer 216 is preferably between 3×10¹¹/cm² and 5×10¹²/cm² inclusive. When the surface concentration of the n-type doping is smaller than 3×10¹¹/cm², spontaneous polarization of the first etching-stopper layer 216 is not sufficiently suppressed, and the effect of reducing the on-resistance cannot be fully obtained. On the other hand, when the surface concentration of the n-type doping is greater than 5×10¹²/cm², electrons flow to layers other than the channel layer 113 having high electron mobility, and so-called parallel conductance occurs. In this case, though the on-resistance is reduced, the controllability of the drain current by the gate voltage is lowered.

Furthermore, the n-type doping needs to be in the first etching-stopper layer 216, and the stopper layer 216A and 216C may not be necessary.

It is to be noted that the n-type doping may be delta doping. Since performing the delta doping on the first etching-stopper layer 216 causes the n-type doping to be localized to each of single atomic layer surfaces, charges are efficiently adjusted at a distance near the interface of the second threshold adjustment layer 217, and the increase in the on-resistance can be suppressed. n-type delta doping to the first etching-stopper layer 216 can be realized by, for example, temporarily suspending epitaxial growth and filling gas including Si.

Moreover, in the first etching-stopper layer 216, an n-type doped region is preferably formed within a distance of 7 nm inclusive from an interface with the second threshold adjustment layer 217. Accordingly, as the n-type doping is performed near the interface where positive charges are accumulated, the on-resistance can be efficiently reduced.

In addition, in the first threshold adjustment layer 216, preferably, the n-type doped region is uniformly doped with a film thickness between 1 nm and 6 nm inclusive. Accordingly, as positive charges accumulated in the upper hetero-interface of the first etching-stopper layer 216 are uniformly reduced across the whole interface in a film surface direction, a barrier to electron conduction is uniformly lowered across the whole interface. Thus, low on-resistance having high reproducibility can be achieved. Furthermore, as the n-type doped region is locally formed in a film-laminating direction, the on-resistance can be reduced with high doping efficiency.

Examples of methods for forming uniform n-type doped region include, for instance, mixing gas including Si in epitaxial film forming of the first etching-stopper layer 216.

The second threshold adjustment layer 217 is a layer that adjusts a threshold voltage of the gate of the D-FET, and, for instance, made of AlGaAs.

In addition, the second threshold adjustment layer 217 may have the same structure as the second threshold value adjustment layer 117 shown in FIG. 1.

Here, a manufacturing process of the semiconductor device according to Embodiment 2 of the present invention will be described.

Each of the layers included in the epitaxial layer 21 is consistently film-formed through, for example, the MOCVD or the MBE.

First, the buffer layers 111 and 112 made of undoped GaAs, the channel layer 113 made of undoped In_{0.2}Ga_{0.8}As and having a film thickness of 10 nm, and the donor layer 114 made of AlGaAs and having a film thickness of 10 nm to which Si is doped are laminated on the semiconductor substrate 10 in this order.

Next, the first threshold adjustment layer 115 made of undoped AlGaAs and having a film thickness of 5 nm is laminated on the donor layer 114.

Next, the stopper layer 216A made of InGaP and the stopper layer 216B having a film thickness of 3 nm are laminated on the first threshold adjustment layer 115, and the stopper layer 216B is doped with n-type doping of Si. Subsequently, the stopper layer 216C made of InGaP is laminated on the n-type doped stopper layer 216B. The n-type doping performed on the stopper layer 216B may be the delta doping. Here, the stopper layers 216A, 216B, and 216C preferably have the disordered structure.

Next, the second threshold adjustment layer 217 made of AlGaAs is laminated on the stopper layer 216C. Here, preferably, the n-type doping is performed on the second threshold adjustment layer 217.

Next, the second etching-stopper layer 118 made of InGaP and having a film thickness of 8 nm is laminated on the second threshold adjustment layer 217. Here, the second etching-stopper layer 118 preferably has the disordered structure. Furthermore, preferably, the n-type doping is uniformly performed on the second etching-stopper layer 118.

Next, the contact layer 119 that includes a lower layer made of n-type GaAs and having a film thickness of 50 nm and an upper layer made of n-type InGaAs and having a film thickness of 50 nm is laminated on the second etching-stopper layer 118.

Next, with respect to the epitaxial layer 11 laminated in the above manner, the isolation region 12, the insulating film 13, the gate electrodes 14D and 14E, and the ohmic electrode 15D and 15E are formed by laminating electrodes and an insulating film and through proper doping processing and etching processing.

As described above, in the semiconductor device 2 in the present embodiment, since the occurrence of charges resulting from the multi-layer heterostructure is controlled and the electron barrier is lowered by including the n-type doped first etching-stopper layer 216 in the semiconductor device 2, the on-resistance against the drain current passing the laminate interface is reduced.

Although the semiconductor device and the manufacturing method thereof have been described above based on the embodiments, the present invention is not limited to the embodiments. Those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be applied to communication devices using GaAsMMIC, and is suitable for power amplifiers or switches of mobile telephone terminals and the like.

What is claimed is:

1. A semiconductor device in which an enhancement-mode field-effect transistor and a depletion-mode field-effect transistor are adjacently integrated in a planar direction of a semiconductor substrate using a semiconductor layer laminated on the semiconductor substrate,
wherein said semiconductor layer includes:
a first threshold adjustment layer that is formed on the semiconductor substrate and adjusts a threshold voltage of a gate of the enhancement-mode field-effect transistor and a threshold voltage of a gate of the depletion-mode field-effect transistor;
a first etching-stopper layer that is formed on said first threshold adjustment layer and stops etching performed from an uppermost layer;
a second threshold adjustment layer that is formed on said first etching-stopper layer and adjusts the threshold voltage of the gate of the depletion-mode field-effect transistor; and
a second etching-stopper layer that is formed on said second threshold adjustment layer and stops the etching performed from the uppermost layer, and
at least one of said first etching-stopper layer and said second threshold adjustment layer includes an n-type doped region.

2. The semiconductor device according to claim 1,
wherein said second etching-stopper layer includes the n-type doped region.

3. The semiconductor device according to claim 1,
wherein said first threshold adjustment layer and said second threshold adjustment layer are made of AlGaAs.

4. The semiconductor device according to claim 1,
wherein said first etching-stopper layer and said second etching-stopper layer are made of InGaP.

5. The semiconductor device according to claim 4,
wherein the InGaP has a disordered structure.

6. The semiconductor device according to claim 1,
wherein said second threshold adjustment layer includes the n-type doped region, and
the n-type doped region is included within a distance of 7 nm inclusive from a contact interface between said second threshold adjustment layer and said first etching-stopper layer.

7. The semiconductor device according to claim 1,
wherein said second threshold adjustment layer includes the n-type doped region, and
the n-type doped region is uniformly doped n-type of a film thickness of between 1 nm and 6 nm inclusive, in the planar direction of the semiconductor substrate.

8. The semiconductor device according to claim 1,
wherein said second threshold adjustment layer includes the n-type doped region, and
the n-type doping is delta doping.

9. The semiconductor device according to claim 1,
wherein said second threshold adjustment layer includes the n-type doped region, and
a surface concentration of the n-type doping is between 3×10¹¹/cm² and 5×10¹²/cm² inclusive.

10. The semiconductor device according to claim 1,
wherein said first etching-stopper layer is uniformly doped n-type.

11. The semiconductor device according to claim 10,
wherein a surface concentration of the n-type doping is between 3×10¹¹/cm² and 5×10¹²/cm² inclusive.

12. The semiconductor device according to claim 1,
wherein said first etching-stopper layer includes the n-type doped region, and
the n-type doping is delta doping.

13. A manufacturing method of a semiconductor device in which an enhancement-mode field-effect transistor and a depletion-mode field-effect transistor are adjacently integrated in a planar direction of a semiconductor substrate using a semiconductor layer laminated on the semiconductor substrate, said method comprising:
forming, on the semiconductor substrate, a first threshold adjustment layer that adjusts a threshold voltage of a gate of the enhancement-mode field-effect transistor and a threshold voltage of a gate of the depletion-mode field-effect transistor;
forming, on the first threshold adjustment layer, a first etching-stopper layer that stops etching performed from an uppermost layer;
forming, on the first etching-stopper layer, a second threshold adjustment layer that adjusts the threshold voltage of the gate of the depletion-mode field-effect transistor;
doping n-type at least one of the first etching-stopper layer and the second threshold adjustment layer; and
forming, on the second threshold adjustment layer, a second etching-stopper layer that stops the etching performed from the uppermost layer.

14. The manufacturing method of the semiconductor device according to claim 13, further comprising
doping n-type the second etching-stopper layer.
